(19) United States
(12) Patent Application Publication
(10) Pub. No.: US 2026/0371577 A1
(43) Pub. Date: Nov. 19, 2026

(54) SEMICONDUCTOR MEMORY DEVICE INCLUDING AN OXIDE SEMICONDUCTOR MATERIAL AND METHOD FOR MANUFACTURING THE SAME

(71) Applicant: Samsung Electronics Co., Ltd., Suwon-si (KR)

(72) Inventor: Dong Kyun LIM, Suwon-si (KR)

(21) Appl. No.: 19/658,114

(22) Filed: Apr. 24, 2026

(30) Foreign Application Priority Data
May 14, 2025 (KR) 10-2025-0062328

(51) Int. Cl. H10B 12/00

(52) U.S. Cl. CPC H10B 12/50; H10B 12/09; H10B 12/315

(57) ABSTRACT

A semiconductor memory device includes a substrate including a first area and a second area, a first active pattern disposed on the first area, a bit line electrically connected to a first portion of the first active pattern, a contact electrode electrically connected to a second portion of the first active pattern, a word line intersecting the first active pattern between the first portion and the second portion, a capacitor electrically connected to an upper surface of the contact electrode, a peripheral circuit layer including a second active pattern disposed on the second area, and a gate electrode intersecting the second active pattern, a first individual device disposed on an upper surface of the peripheral circuit layer, the first individual device being disposed at a vertical level between a lower surface of the capacitor and an upper surface of the capacitor, wherein the first individual device includes a first semiconductor layer including a first oxide semiconductor material, and a first gate pattern intersecting the first semiconductor layer in a plan view.

### CROSS-REFERENCE TO RELATED APPLICATION

This application claims priority from Korean Patent Application No. 10-2025-0062328filed on May 14, 2025 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor memory device and a method for manufacturing the same. More specifically, the present disclosure relates to a semiconductor memory device including a capacitor and a method for manufacturing the same.

### Description of Related Art

As semiconductor memory devices become more highly integrated, individual circuit patterns are becoming more refined in order to implement a larger number of semiconductor memory devices in the same area. However, the miniaturization of the individual circuit patterns increases the process difficulty and causes defects. Accordingly, various methods for manufacturing a semiconductor memory device having better performance while overcoming limitations due to high integration of the semiconductor memory device have been studied.

### SUMMARY

A technical purpose to be achieved by the present disclosure is to provide a semiconductor memory device with improved performance and integration.

Another technical purpose to be achieved by the present disclosure is to provide a method for manufacturing a semiconductor memory device with improved performance and integration.

The technical purposes of the present invention are not limited to the above-mentioned technical purposes, and other technical purposes not mentioned may be clearly understood by a person skilled in the art from the following description.

According to an aspect of the present inventive concept, there is provided a semiconductor memory device comprising a substrate including a first area and a second area and a unit cell including. The unit cell includes: a first active pattern disposed on the first area, a bit line electrically connected to a first portion of the first active pattern, a contact electrode electrically connected to a second portion of the first active pattern, a word line intersecting the first active pattern between the first portion and the second portion, and a capacitor electrically connected to an upper surface of the contact electrode. The semiconductor memory device further comprising: a peripheral circuit layer including a second active pattern disposed on the second area, and a gate electrode intersecting the second active pattern, a first individual device disposed on an upper surface of the peripheral circuit layer, the first individual device being disposed at a vertical level between a lower surface of the capacitor and an upper surface of the capacitor, wherein the first individual device includes a first semiconductor layer including a first oxide semiconductor material, and a first gate pattern intersecting the first semiconductor layer in a plan view.

According to an aspect of the present inventive concept, there is provided a semiconductor memory device comprising a substrate including a first area and a second area, a first active pattern disposed on the first area, a bit line electrically connected to a first portion of the first active pattern, a capacitor including a lower electrode pattern electrically connected to a second portion of the first active pattern, a support pattern disposed on a side surface of the lower electrode pattern, and a capacitor dielectric film and an upper electrode pattern sequentially stacked on the lower electrode pattern and the support pattern, a word line intersecting the first active pattern between the first portion and the second portion, a peripheral circuit layer including a second active pattern disposed on the second area, and a gate electrode intersecting the second active pattern, a support layer disposed on an upper surface of the peripheral circuit layer, the support pattern and the support layer being disposed at the same vertical level, a first transistor disposed on an upper surface of the support layer, the first transistor including a first semiconductor layer including a first oxide semiconductor material, and a first gate pattern intersecting the first semiconductor layer, and a second transistor disposed on the upper surface of the support layer, the second transistor including a second semiconductor layer including a second oxide semiconductor material, and a second gate pattern intersecting the second semiconductor layer, wherein the first transistor has a first threshold voltage, wherein the second transistor has a second threshold voltage greater than the first threshold voltage.

According to an aspect of the present inventive concept, there is provided a semiconductor memory device comprising a substrate including a first area and a second area, a first active pattern disposed on the first area, a bit line electrically connected to a first portion of the first active pattern, a capacitor including: a lower electrode pattern electrically connected to a second portion of the first active pattern, a support pattern disposed on a side surface of the lower electrode pattern, and a capacitor dielectric film and an upper electrode pattern sequentially stacked on the lower electrode pattern and the support pattern, a word line intersecting the first active pattern between the first portion and the second portion, a peripheral circuit layer including a second active pattern disposed on the second area, and a gate electrode intersecting the second active pattern, a support layer disposed on an upper surface of the peripheral circuit layer, the support layer and the support pattern being disposed at the same vertical level, and a first individual device disposed on an upper surface of the support layer, the first individual device including a first semiconductor layer including an oxide semiconductor material, and an electrode pattern in contact with the first semiconductor layer. The first individual device is configured to be programmed by applying a predetermined voltage into the first semiconductor layer through the electrode pattern.

Specific details of other embodiments are included in the detailed description and drawings.

### BRIEF DESCRIPTION OF DRAWINGS

The above and other aspects and features of the present disclosure will become more apparent by illustrating in detail embodiments thereof with reference to the attached drawings.

FIG. 1 is an example layout diagram for illustrating a semiconductor memory device according to some embodiments.

FIG. 2 is a cross-sectional view illustrating a cell area and a peripheral circuit area of FIG. 1.

FIGS. 3A to 3C are various enlarged views for illustrating an area R1 of FIG. 2.

FIGS. 4A to 4E are various enlarged views for illustrating an area R2 of FIG. 2.

FIG. 5 is an example circuit diagram for illustrating an electronic circuit implemented using the circuit elements of FIG. 2.

FIG. 6 is a cross-sectional view illustrating a semiconductor memory device according to some embodiments.

FIG. 7 is a cross-sectional view illustrating a semiconductor memory device according to some embodiments.

FIGS. 8 to 30 are diagrams for illustrating intermediate structures corresponding to intermediate steps of a method for manufacturing a semiconductor memory device according to some embodiments.

### DETAILED DESCRIPTIONS

The terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, the terms “same” and “equal” may mean not only exactly the same thing but also include a slight difference that may occur due to a process margin or the like. The term “substantially” may be used herein to emphasize this meaning.

It will be understood that, although the terms “first,” “second,” etc. may be used herein to describe various elements, these elements should not be limited by the ordinary terms. These ordinary terms are only used to distinguish one element from another element. Thus, for example, terms that are not described using “first,” “second,” etc., in the specification, may still be referred to as “first” or “second” in a claim. In addition, a first element, a first component or a first section discussed below (e.g., “first” in a particular claim) could be termed a second element, a second component or a second section (e.g., “second” in the specification or another claim) without departing from the teachings of the present inventive concept.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

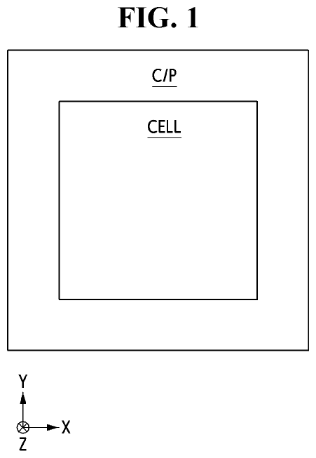

Hereinafter, a semiconductor memory device according to some embodiments will be described with reference to FIGS. 1 to 7.

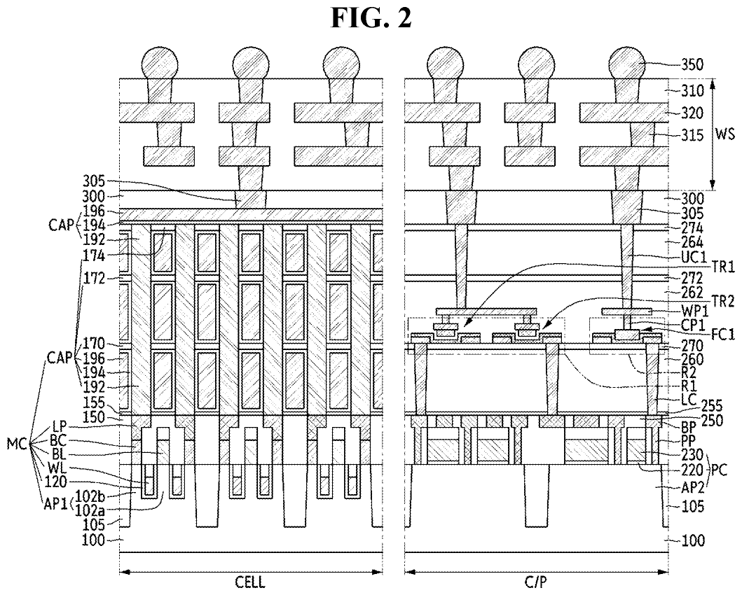

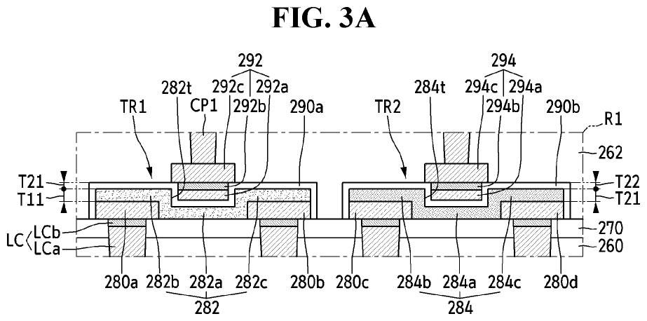

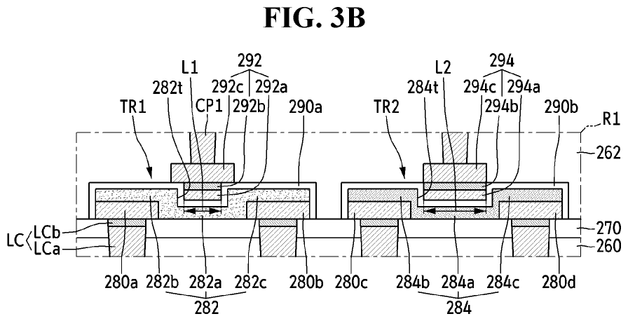

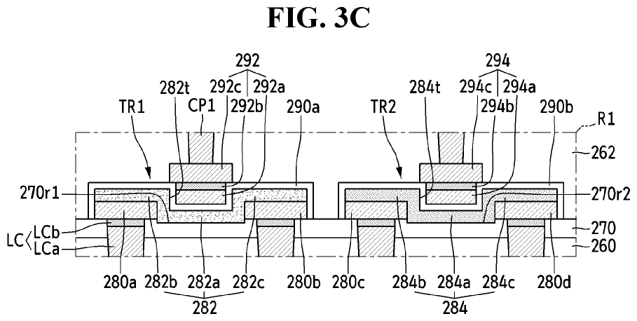

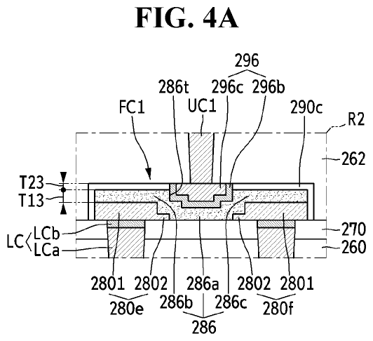

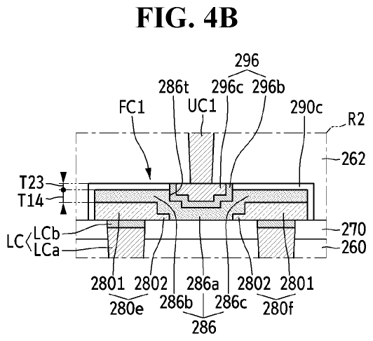

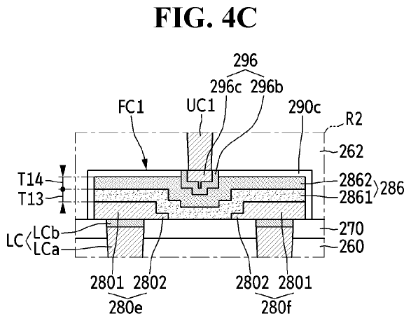

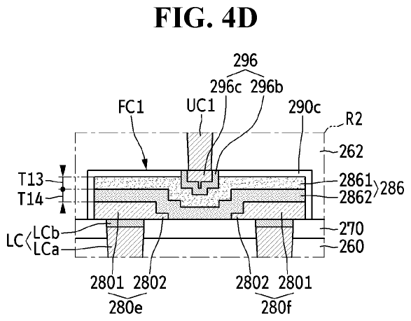

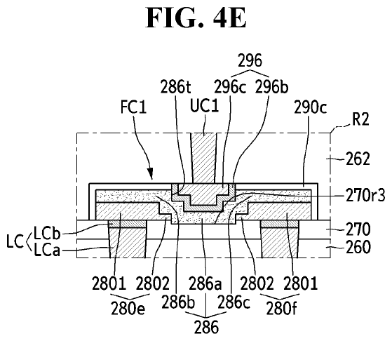

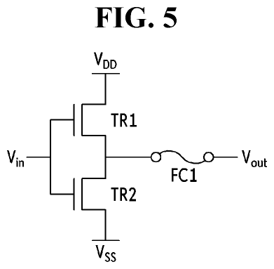

FIG. 1 is an example layout diagram for illustrating a semiconductor memory device according to some embodiments. In the drawings, each cross-sectional view may show a vertical section taken in a plane defined by the X and Z axes or by the Y and Z axes of FIG. 1. FIG. 2 is a cross-sectional view illustrating a cell area and a peripheral circuit area (or core/peripheral area) of FIG. 1. FIGS. 3A to 3C are various enlarged views for illustrating an area R1 of FIG. 2. FIGS. 4A to 4E are various enlarged views for illustrating an area R2 of FIG. 2. FIG. 5 is an example circuit diagram for illustrating an electronic circuit implemented using the circuit elements of FIG. 2.

Referring to FIGS. 1 to 5, the semiconductor memory device according to some embodiments includes a substrate 100, an element isolation pattern 105, a memory cell structure MC (or unit cell), a peripheral circuit structure (or peripheral circuit layer) PC, a plug pattern PP, a peripheral circuit wiring BP, circuit elements (or individual devices) TR1, TR2, and FC1, a wiring structure (or a plurality of wiring patterns) WS, and a contact terminal 350.

The substrate 100 may be a semiconductor substrate such as a silicon wafer (or a part of a silicon wafer). The substrate 100 may have a structure in which a base substrate and an epitaxial layer are stacked. However, embodiments of the present disclosure are not limited thereto. The substrate 100 may be a silicon substrate, a gallium arsenide substrate, a silicon germanium substrate, or a semiconductor on insulator (SOI) substrate. In following descriptions, an example in which the substrate 100 is embodied as the silicon substrate will be set forth.

The substrate 100 may include a first area CELL and a second area C/P. The first area CELL may be a memory cell array area in which memory cells are disposed. The second area C/P may be a core/peripheral area formed around the first area CELL. Some control elements and dummy elements may be formed on the second area C/P to control functions of the memory cells formed on the first area CELL. Although it is illustrated that the second area C/P surrounds the first area CELL, this is only an example, and the first area CELL and the second area C/P may be arranged in various other forms.

The element isolation pattern 105 may be formed on the substrate 100. The element isolation pattern 105 may constitute an insulating area on the substrate 100. For example, the element isolation pattern 105 may be embodied as a shallow trench isolation (STI). The element isolation pattern 105 may include an insulating material, for example, at least one of silicon oxide, silicon nitride, silicon oxynitride, silicon oxycarbonitride, or a combination thereof. However, embodiments of the present disclosure are not limited thereto. The element isolation pattern 105 may be embodied as a single film made of one type of insulating material or may be embodied as a stack of multiple films made of a combination of various types of insulating materials.

The memory cell structure MC (or unit cell) may be formed on the first area CELL of the substrate 100. Each of the unit cells MC may include a first active pattern AP1, a first gate dielectric film 120, a word line WL, a bit line BL, a contact structure (or contact electrode) BC and LP, and a capacitor structure (or capacitor) CAP.

In some embodiments, each of the unit cells MC may include a corresponding portion of a first active pattern AP1, a corresponding portion of a first gate dielectric film, a corresponding portion of a word line, a corresponding portion of a bit line, a contact structure BC and LP, and a capacitor structure CAP.

For example, the first active pattern AP1, the first gate dielectric film 120 and the word line WL may constitute a cell transistor. For example, the first active pattern AP1 (or the cell transistor) may be configured for current to flow in a horizontal direction. In some embodiments, the first active pattern AP1 (or the cell transistor) may be configured for current to flow in a vertical direction.

The first active pattern AP1 may be formed on (or with or as part of) the substrate 100 in the first area CELL. For example, the element isolation pattern 105 on the first area CELL may define a plurality of first active patterns AP1 spaced apart from each other on the first area CELL of the substrate 100. For example, the substrate 100 and the first active pattern AP1 may have material continuity or may not. Reference to the substrate 100 being provided with the first active pattern AP1 or reference to the first active pattern AP1 being provided with the substrate 100 are intended to encompass these alternatives. Accordingly, as used herein, the term “substrate” should not be interpreted as requiring materially distinctiveness from the first active pattern AP1.

The bit line BL may be formed on the first active pattern AP1. The bit line BL may extend in an elongate manner in a first direction X. The plurality of bit lines BL may be spaced apart from each other and extend in a parallel manner to each other. The bit line BL may contact and/or be electrically connected to a first portion (or a source/drain area of a cell transistor) 102a of the first active pattern AP1.

In some embodiments, the first portion 102a may be a central portion of the first active pattern AP1.

The contact structure BC and LP may be formed on the first active pattern AP1. The contact structure BC and LP may contact and be electrically connected to a second portion (or a source/drain area of a cell transistor) 102b of the first active pattern AP1. For example, a first lower interlayer insulating film 150 covering the first active pattern AP1 and the bit line BL may be formed on the first area CELL of the substrate 100. The contact structure BC and LP may extend through the first lower interlayer insulating film 150 and may contact and be electrically connected to the second portion 102b.

In some embodiments, the second portion 102b may be an end portion of the first active pattern AP1.

In some embodiments, the contact structure BC and LP may include a buried contact BC and a landing pad LP, which are sequentially stacked on the first active pattern AP1. The buried contact BC may contact and be electrically connected to an upper surface of the second portion 102b. The landing pad LP may contact and be electrically connected to an upper surface of the buried contact BC.

The buried contact BC may include at least one of a conductive material, for example, polysilicon, TiN, TiSiN, tungsten, tungsten silicide, and a combination thereof. However, embodiments of the present disclosure are not limited thereto. For example, the buried contact BC may include a polysilicon (poly-Si) film.

The landing pad LP may include at least one of a conductive material, for example, polysilicon, TiN, TiSiN, tungsten, tungsten silicide, and a combination thereof. However, embodiments of the present disclosure are not limited thereto. For example, the landing pad LP may include tungsten (W).

The word line WL may be formed on the first active pattern AP1. A first gate dielectric film 120 may be interposed between the first active pattern AP1 and the word line WL. The word line WL may be spaced apart from the first active pattern AP1 via (or by) the first gate dielectric film 120. The word line WL may extend in an elongate manner in a second direction Y intersecting the first direction X. The plurality of word lines WL may be spaced apart from each other and extend in a parallel manner to each other. The word line WL may intersect the first active pattern AP1 while being disposed between the first portion 102a and the second portion 102b. For example, the first active pattern AP1 may extend in a diagonal direction between the first direction X and the second direction Y. The bit line BL and the contact structure BC and LP may be arranged in the diagonal direction.

In some embodiments, the word line WL may be buried in the substrate 100. For example, a word line trench WLT extending in an elongate manner in the second direction Y may be formed in the first active pattern AP1 and the element isolation pattern 105. The first gate dielectric film 120 may conformally extend along a profile of the word line trench WTR. The word line WL may fill at least a portion of the word line trench remaining after the first gate dielectric film 120 has been formed therein.

In some embodiments, a vertical level of an upper surface of the word line WL may be lower than a vertical level of an upper surface of the first active pattern AP1 and/or an upper surface of the element isolation pattern 105.

The capacitor structure CAP may be formed on an upper surface of the bit line BL and an upper surface of the contact structure BC and LP. For example, a first etch stop film 155 may be formed on the first lower interlayer insulating film 150. The capacitor structure CAP may be formed on an upper surface of the first etch stop film 155. The capacitor structure CAP may be electrically connected to the second portion 102b of the first active pattern AP1 via the contact structure BC and LP.

The capacitor structure CAP may be controlled by the bit line BL and the word line WL so as to be configured to store data therein. For example, the capacitor structure CAP may include a lower electrode pattern 192, a capacitor dielectric film 194, and an upper electrode pattern 196 (e.g., a corresponding portion of an upper electrode pattern). The lower electrode pattern 192 may extend through the first etch stop film 155 so as to contact and be electrically connected to the upper surface of the contact structure BC and LP. The upper electrode pattern 196 may face the lower electrode pattern 192. The capacitor dielectric film 194 may be interposed between the lower electrode pattern 192 and the upper electrode pattern 196. The capacitor structure CAP may store charges in the capacitor dielectric film 194 using a potential difference generated between the lower electrode pattern 192 and the upper electrode pattern 196.

In some embodiments, the lower electrode pattern 192 may have a pillar shape extending in an elongate manner in a vertical direction (z-direction) intersecting an upper surface of the substrate 100.

In some embodiments, the capacitor structure CAP may include a first support pattern 170, a second support pattern 172, and a third support pattern 174. Each of the first support pattern 170, the second support pattern 172, and the third support pattern 174 may be formed on a side surface of the lower electrode pattern 192. The first support pattern 170, the second support pattern 172, and the third support pattern 174 may be spaced apart from each other in the vertical direction. For example, the first support pattern 170 may be spaced apart from an upper surface of the first etch stop film 155. The second support pattern 172 may be spaced apart from an upper surface of the first support pattern 170. The third support pattern 174 may be spaced apart from an upper surface of the second support pattern 172. Each of the first support pattern 170, the second support pattern 172, and the third support pattern 174 may be interposed between adjacent lower electrode patterns 192 to prevent or suppress the lower electrode patterns 192 having a high aspect ratio from being tilted or collapsed.

Each of the first support pattern 170, the second support pattern 172, and the third support pattern 174 may include an insulating material, for example, at least one of silicon oxide, silicon nitride, silicon oxynitride, silicon oxycarbonitride, or a combination thereof. However, embodiments of the present disclosure are not limited thereto. For example, each of the first support pattern 170, the second support pattern 172, and the third support pattern 174 may include a silicon nitride film. In FIG. 2, the number, thickness, shape, and/or arrangement of each of the support patterns 170, 172, and 174 are only exemplary, and are not limited to those illustrated.

The peripheral circuit structure PC may be formed on the second area C/P of the substrate 100. The peripheral circuit structure PC may control a function of the memory cell structure MC on the first area CELL. The peripheral circuit structure PC may include a plurality of individual devices (e.g., various active elements such as a transistor, as well as various passive elements such as a capacitor, a resistor, and an inductor).

In some embodiments, the peripheral circuit structure PC may include a second active pattern AP2, a second gate dielectric film 220, and a gate electrode 230. For example, the second active pattern AP2, the second gate dielectric film 220, and the gate electrode 230 may constitute a peripheral transistor. Though not shown in the drawings, in a plan view, the portions of the second active pattern AP2 that are adjacent to the two opposite edges of the gate electrode 230 and that do not overlap with the gate electrode 230 may correspond to source and drain regions of the peripheral transistor.

The second active pattern AP2 may be formed on (or with or as part of) the substrate 100 in the second area C/P. For example, the element isolation pattern 105 on the second area C/P may define a plurality of second active patterns AP2 spaced apart from each other on the second area C/P of the substrate 100. For example, the substrate 100 and the second active pattern AP2 may have material continuity or may not. Reference to the substrate 100 being provided with the second active pattern AP2 or reference to the second active pattern AP2 being provided with the substrate 100 are intended to encompass these alternatives. Accordingly, as used herein, the term “substrate” should not be interpreted as requiring materially distinctiveness from the second active pattern AP2.

The second gate dielectric film 220 may be interposed between the second active pattern AP2 and the gate electrode 230. For example, the second gate dielectric film 220 may conformally extend along an upper surface of the second active pattern AP2. The second gate dielectric film 220 may include, for example, at least one of silicon oxide, silicon oxynitride, silicon nitride, and a high dielectric constant (high-k) material having a dielectric constant greater than that of silicon oxide. However, embodiments of the present disclosure are not limited thereto.

The gate electrode 230 may be formed on an upper surface of the second gate dielectric film 220. The gate electrode 230 may be spaced apart from the second active pattern AP2 via the second gate dielectric film 220.

In some embodiments, the gate electrode 230 may be formed at the same level as that of the bit line BL. As used herein, being formed at the same level may mean being formed in the same manufacturing process, but the phrase is not limited to such cases. For example, the gate electrode 230 may include the same conductive material (or the same material composition) as that of the bit line BL.

A plug pattern PP may be formed on the second active pattern AP2. The plug pattern PP may be formed on a side surface of the gate electrode 230. The plug pattern PP may contact and be electrically connected to the second active pattern AP2 (or source/drain areas). For example, a second lower interlayer insulating film 250 covering the second active pattern AP2 and the gate electrode 230 may be formed on the second area C/P of the substrate 100. The plug pattern PP may extend through the second lower interlayer insulating film 250 so as to contact and be electrically connected to the second active pattern AP2.

A peripheral circuit wiring BP may be formed on an upper surface of the gate electrode 230. The plug pattern PP may electrically connect the second active pattern AP2 to the peripheral circuit wiring BP. The peripheral circuit wiring BP may constitute a wiring structure for the peripheral circuit structure PC.

In some embodiments, the plug pattern PP and/or the peripheral circuit wiring BP may be formed at the same level (vertical level) as that of the landing pad LP. For example, the plug pattern PP and/or the peripheral circuit wiring BP may include the same conductive material (or the same material composition) as that of the landing pad LP.

The circuit elements TR1, TR2, and FC1 may be formed on an upper surface of the peripheral circuit structure PC. For example, a second etch stop film 255 and interlayer insulating films 260, 262, and 264 may be sequentially stacked on the second lower interlayer insulating film 250. The circuit elements TR1, TR2, and FC1 may be formed in the interlayer insulating films 260, 262, and 264. The circuit elements TR1, TR2, and FC1 may overlap the capacitor structure CAP in a horizontal direction (e.g., the first direction X or the second direction Y) parallel to the upper surface of the substrate 100. For example, each of the circuit elements TR1, TR2, and FC1 may be disposed at a vertical level between a vertical level of a lower surface of the capacitor structure CAP and a vertical level of an upper surface of the capacitor structure CAP.

In some embodiments, the first interlayer insulating film 260, the first support layer 270, the second interlayer insulating film 262, a second support layer 272, a third interlayer insulating film 264, and a third support layer 274 may be sequentially stacked on the second etch stop film 255. As illustrated in FIG. 2, the first support layer 270, the second support layer 272, and the third support layer 274 may be disposed at the same level as that of the first support pattern 170, the second support pattern 172, and the third support pattern 174, respectively. As used herein, being disposed at the same level means being positioned at the same vertical level, e.g., based on the upper surface of the substrate 100. For example, based on the upper surface of the substrate 100, the vertical level of the lower surface of the first support pattern 170 and the vertical level of the lower surface of the first support layer 270 may be equal to each other.

Each of the first support layer 270, the second support layer 272, and the third support layer 274 may be formed at the same level as that of each of the first support pattern 170, the second support pattern 172, and the third support pattern 174. For example, the first support layer 270 may include the same insulating material (or the same material composition) as that of the first support pattern 170.

In some embodiments, the circuit elements TR1, TR2, and FC1 may be formed on an upper surface of the first support layer 270. The second interlayer insulating film 262 may cover the circuit elements TR1, TR2, and FC1.

In some embodiments, at least some of the circuit elements TR1, TR2, and FC1 may be electrically connected to the peripheral circuit structure PC. For example, a lower contact LC may be formed to extend through the second etch stop film 255, the first interlayer insulating film 260, and the first support layer 270. At least some of the circuit elements TR1, TR2, and FC1 may be electrically connected to the peripheral circuit wiring BP via the lower contact LC.

In some embodiments, at least some of the circuit elements TR1, TR2, and FC1 may be electrically connected to each other. For example, a first contact pattern CP1 (which contacts and is electrically connected to each of the circuit elements TR1, TR2, and FC1) may be formed in the second interlayer insulating film 262. In addition, a first connection pattern WP1 contacting and electrically connected to the first contact pattern CP1 may be formed in the second interlayer insulating film 262. At least some of the circuit elements TR1, TR2, and FC1 may be electrically connected to each other via the first contact pattern CP1 and/or the first connection pattern WP1.

The circuit elements TR1, TR2, and FC1 may include a first circuit element TR1, a second circuit element TR2, and a third circuit element FC1, each including an oxide semiconductor material. The oxide semiconductor material may include a semiconductor material composed of a metal oxide compound, and may include, for example, at least one of IGZO (indium gallium zinc oxide, InₓGa_{y}Zn_{z}O), IGSO (indium gallium silicon oxide, InₓGa_{y}Si_{z}O), ITZO (indium tin zinc oxide, InₓSn_{y}Zn_{z}O), IZO (indium zinc oxide, InₓZn_{y}O), ZnO (zinc oxide, ZnₓO), ZTO (zinc tin oxide, ZnₓSn_{y}O), ZnON (zinc oxynitride, ZnₓO_{y}N), ZZTO (zirconium zinc tin oxide, ZrₓZn_{y}Sn_{z}O), SnO (tin oxide, SnₓO), HIZO (hafnium indium zinc oxide, HfₓIn_{y}Zn_{z}O), GZTO (gallium zinc tin oxide, GaₓZn_{y}Sn_{z}O), AZTO (aluminum zinc tin oxide, AlₓZn_{y}Sn_{z}O), YGZO (ytterbium gallium zinc oxide, YbₓGa_{y}Zn_{z}O), IGO (indium gallium oxide, InₓGa_{y}O), or combinations thereof. For example, the oxide semiconductor material may be IGZO.

The wiring structure WS may be formed on the upper surface of the memory cell structure MC and the upper surfaces of the circuit elements TR1, TR2, and FC1. For example, an upper interlayer insulating film 300 covering an upper surface of the capacitor structure CAP and an upper surface of the third support layer 274 may be formed. The wiring structure WS may be formed on an upper surface of the upper interlayer insulating film 300.

The wiring structure WS may provide a multi-layered wiring structure. For example, the wiring structure WS may include an inter-wiring insulating film 310, wiring patterns 320, and via patterns 315. The wiring patterns 320 may provide an electrical path having a multilayer structure in the inter-wiring insulating film 310. The via patterns 315 may interconnect the wiring patterns 320 of different layers to each other. For example, the wiring structure WS may be a plurality of metal wiring patterns provided with inter-wiring insulating films 310. The plurality of metal wiring patterns may include wiring patterns 320 and via patterns 315. The plurality of wiring patterns may be provided in the form of a multilayer structure (conductive layer stack comprising a plurality of stacked sub-layers). In FIG. 2, the number of layers, the number, the shape, and the arrangement of each of the inter-wiring insulating film 310, the wiring patterns 320, and the via patterns 315 are only exemplary, and are not limited to those illustrated.

In some embodiments, the wiring structure WS on the first area CELL may be electrically connected to the memory cell structure MC. For example, a via contact 305 may be formed to extend through the upper interlayer insulating film 300 so as to contact and be electrically connected to the upper electrode pattern 196. The wiring structure WS may be electrically connected to the capacitor structure CAP via the via contact 305.

In some embodiments, the wiring structure WS on the second area C/P may be electrically connected to the peripheral circuit structure PC and/or the circuit elements TR1, TR2, and FC1. For example, a first upper contact UC1 may be formed to extend through the second support layer 272, the third interlayer insulating film 264, and the third support layer 274 so as to contact and be electrically connected to the first connection pattern WP1. The wiring structure WS may be electrically connected to the circuit elements TR1, TR2, and FC1 via the first upper contact UC1 and/or the via contact 305.

The contact terminal 350 may be formed on the wiring structure WS. The contact terminal 350 may be electrically connected to the wiring structure WS. The contact terminal 350 may be, for example, a solder ball solder ball or a bump. However, embodiments of the present disclosure are not limited thereto. The memory cell structure MC, the peripheral circuit structure PC, and/or the circuit elements TR1, TR2, and FC1 may be electrically connected to an external electronic device via the contact terminal 350.

In some embodiments, each of the first circuit element TR1 and the second circuit element TR2 may be provided as a transistor (e.g., thin film transistor). As used herein, the first circuit element TR1 may also be referred to as a first transistor, and the second circuit element TR2 may also be referred to as a second transistor. Each of the first circuit element TR1 and the second circuit element TR2 may be configured for current to flow in a horizontal direction. In some embodiments, the first active pattern AP1 (or the cell transistor) may be configured for current to flow in a first direction which is different from (e.g., perpendicular to) a second direction, in which current flows in the first circuit element TR1 and/or the second circuit element TR2.

As illustrated in FIGS. 3A to 3C, the first circuit element TR1 may include a first source/drain pattern 280a, a second source/drain pattern 280b, a first semiconductor layer 282, a first gate dielectric pattern 290a, and a first gate pattern 292.

Each of the first source/drain pattern 280a and the second source/drain pattern 280b may be formed on an upper surface of the first support layer 270. The first source/drain pattern 280a and the second source/drain pattern 280b may be spaced apart from each other in a horizontal direction (e.g., the first direction X or the second direction Y) parallel to the upper surface of the substrate 100.

The first semiconductor layer 282 may connect the first source/drain pattern 280a and the second source/drain pattern 280b to each other. For example, the first semiconductor layer 282 may include a first channel area 282a, a first source/drain area 282b and a second source/drain area 282c. The first source/drain area 282b and the second source/drain area 282c may be connected to opposing ends of the first channel area 282a, respectively. The first source/drain area 282b may contact and be electrically connected to the first source/drain pattern 280a, and the second source/drain area 282c may contact and be electrically connected to the second source/drain pattern 280b.

In some embodiments, the first semiconductor layer 282 may be formed on an upper surface of the first source/drain pattern 280a and an upper surface of the second source/drain pattern 280b. For example, the first semiconductor layer 282 may conformally extend along a profile of an upper surface of the first support layer 270, side and upper surfaces of the first source/drain pattern 280a, and side and upper surfaces of the second source/drain pattern 280b. Accordingly, a first trench (or recess) 282t may be defined in an upper surface of the first semiconductor layer 282 so as to be recessed downwardly.

The first gate dielectric pattern 290a may be formed on the first semiconductor layer 282. The first gate dielectric pattern 290a may be interposed between the first semiconductor layer 282 and the first gate pattern 292. For example, the first gate dielectric pattern 290a may conformally extend along a profile of an upper surface and the side surface of the first semiconductor layer 282, the side surface of the first source/drain pattern 280a, and the side surface of the second source/drain pattern 280b. Unlike the illustrated example, the first gate dielectric pattern 290a may further extend along and along an upper surface of the first support layer 270.

The first gate pattern 292 may be formed on the first semiconductor layer 282. The first gate pattern 292 may be spaced apart from the first semiconductor layer 282 via (by) the first gate dielectric pattern 290a. The first gate pattern 292 may intersect the first semiconductor layer 282 in a plan view. For example, the first gate pattern 292 may intersect the first channel area 282a while being disposed between the first source/drain area 282b and the second source/drain area 282c. The first gate pattern 292 may be provided as a gate for controlling on/off of the first circuit element TR1 provided as the first transistor.

In some embodiments, the first gate pattern 292 may fill at least a portion of the first trench 282t.

As illustrated in FIGS. 3A to 3C, the second circuit element TR2 may include a third source/drain pattern 280c, a fourth source/drain pattern 280d, a second semiconductor layer 284, a second gate dielectric pattern 290b, and a second gate pattern 294.

Each of the third source/drain pattern 280c and the fourth source/drain pattern 280d may be formed on the upper surface of the first support layer 270. The third source/drain pattern 280c and the fourth source/drain pattern 280d may be spaced apart from each other in a horizontal direction (e.g., the first direction X or the second direction Y) parallel to the upper surface of the substrate 100.

The second semiconductor layer 284 may connect the third source/drain pattern 280c and the fourth source/drain pattern 280d to each other. For example, the second semiconductor layer 284 may include a second channel area 284a, a third source/drain area 284b and a fourth source/drain area 284c. The third source/drain area 284b and the fourth source/drain area 284c may be connected to opposing ends of the second channel area 284a, respectively. The third source/drain area 284b may contact and be electrically connected to the third source/drain pattern 280c, and the fourth source/drain area 284c may contact and be electrically connected to the fourth source/drain pattern 280d.

In some embodiments, the second semiconductor layer 284 may be formed on an upper surface of the third source/drain pattern 280c and an upper surface of the fourth source/drain pattern 280d. For example, the second semiconductor layer 284 may conformally extend along a profile of the upper surface of the first support layer 270, side and upper surfaces of the third source/drain pattern 280c, and side and upper surfaces of the fourth source/drain pattern 280d. Accordingly, a second trench 284t may be defined in an upper surface of the second semiconductor layer 284 so as to be recessed downwardly.

The second gate dielectric pattern 290b may be formed on the second semiconductor layer 284. The second gate dielectric pattern 290b may be interposed between the second semiconductor layer 284 and the second gate pattern 294. For example, the second gate dielectric pattern 290b may conformally extend along a profile of the upper surface and the side surface of the second semiconductor layer 284, the side surface of the third source/drain pattern 280c, and the side surface of the fourth source/drain pattern 280d. Unlike the illustrated example, the second gate dielectric pattern 290b may further extend along and on the upper surface of the first support layer 270.

The second gate pattern 294 may be formed on the second semiconductor layer 284. The second gate pattern 294 may be spaced apart from the second semiconductor layer 284 via (by) the second gate dielectric pattern 290b. The second gate pattern 294 may intersect the second semiconductor layer 284 in a plan view. For example, the second gate pattern 294 may intersect the second channel area 284a while being disposed between the third source/drain area 284b and the fourth source/drain area 284c. The second gate pattern 294 may be provided as a gate for controlling on/off of the second circuit element TR2 provided as the second transistor.

In some embodiments, the second gate pattern 294 may fill at least a portion of the second trench 284t.

In some embodiments, the third circuit element FC1 may be provided as a fuse circuit and/or an anti-fuse circuit. As used herein, the third circuit element FC1 may also be referred to as a fuse circuit element and/or an anti-fuse circuit element.

As illustrated in FIGS. 4A to 4E, the third circuit element FC1 may include a fifth source/drain pattern 280e, a sixth source/drain pattern 280f, a third semiconductor layer 286, a third gate dielectric pattern 290c, and a third gate pattern 296.

Each of the fifth source/drain pattern 280e and the sixth source/drain pattern 280f may be formed on the upper surface of the first support layer 270. The fifth source/drain pattern 280e and the sixth source/drain pattern 280f may be spaced apart from each other in a horizontal direction (e.g., the first direction X or the second direction Y) parallel to the upper surface of the substrate 100.

The third semiconductor layer 286 may connect the fifth source/drain pattern 280e and the sixth source/drain pattern 280f to each other. For example, the third semiconductor layer 286 may include a third channel area 286a, a fifth source/drain area 286b and a sixth source/drain area 286c. The fifth source/drain area 286b and the sixth source/drain area 286c may be connected to opposing ends of the third channel area 286a, respectively. The fifth source/drain area 286b may contact and be electrically connected to the fifth source/drain pattern 280e, and the sixth source/drain area 286c may contact and be electrically connected to the sixth source/drain pattern 280f.

In some embodiments, the third semiconductor layer 286 may be formed on an upper surface of the fifth source/drain pattern 280e and an upper surface of the sixth source/drain pattern 280f. For example, the third semiconductor layer 286 may conformally extend along a profile of the upper surface of the first support layer 270, side and upper surfaces of the fifth source/drain pattern 280e, and side and upper surfaces of the sixth source/drain pattern 280f. Accordingly, a third trench 286t may be defined in an upper surface of the third semiconductor layer 286 so as to be recessed downwardly.

The third gate dielectric pattern 290c may be formed on the third semiconductor layer 286. The third gate dielectric pattern 290c may not be interposed between the third semiconductor layer 286 and the third gate pattern 296. For example, the third gate dielectric pattern 290c may conformally extend along a profile of the side surface of the third gate pattern 296, the upper surface and the side surface of the third semiconductor layer 286, the side surface of the third source/drain pattern 280c, and the side surface of the fourth source/drain pattern 280d. Unlike the illustrated example, the third gate dielectric pattern 290c may further extend along and on the upper surface of the first support layer 270.

The third gate pattern 296 may be formed on the third semiconductor layer 286. In some embodiments, the third gate pattern 296 may be in contact with an upper surface of the third semiconductor layer 286. The third gate pattern 296 may intersect the third semiconductor layer 286. For example, the third gate pattern 296 may intersect the third channel area 286a in a plan view while being disposed between the fifth source/drain area 286b and the sixth source/drain area 286c. The third gate pattern 296 may be provided as a gate (or electrode pattern) for applying a predetermined voltage to the third semiconductor layer 286 to control an open/short of the third circuit element FC1 provided as a fuse circuit element and/or an anti-fuse circuit element. For example, by applying a predetermined voltage into the third semiconductor layer 286 through the electrode pattern 296, the fuse or the anti-fuse may be configured to be programmed to select a predetermined operating mode.

In some embodiments, the third gate pattern 296 may fill at least a portion of the third trench 286t.

Each of the source/drain patterns 280a to 280f may include a conductive material, for example, at least one of polysilicon, TiN, TiSiN, tungsten, tungsten silicide, and a combination thereof. However, embodiments of the present disclosure are not limited thereto. For example, each of the source/drain patterns 280a to 280f may include an amorphous polysilicon film.

In some embodiments, at least some of the source/drain patterns 280a to 280f may contact and be electrically connected to the lower contact LC. For example, a bottom surface of each of at least some of the source/drain patterns 280a to 280f may be in contact with an upper surface of the lower contact LC.

In some embodiments, as illustrated in FIGS. 4A to 4E, each of the fifth source/drain pattern 280e and/or the sixth source/drain pattern 280f may include a base portion 2801 and a protrusion portion 2802. The base portion 2801 may be in contact with the upper surface of the lower contact LC. The protrusion portion 2802 may protrude from the base portion 2801 toward the third channel area 286a.

In some embodiments, the lower contact LC may include a pillar pattern LCa and a lower interfacial layer LCb. The pillar pattern LCa may include a conductive material, for example, at least one of aluminum (Al), copper (Cu), tungsten (W), molybdenum (Mo), cobalt (Co), or alloys thereof. However, embodiments of the present disclosure are not limited thereto. The lower interfacial layer LCb may be interposed between the pillar pattern LCa and the source/drain patterns 280a to 280f. The lower interfacial layer LCb may include, for example, a metal or a metal nitride for preventing or suppressing diffusion of a metal element included in the pillar pattern LCa. For example, the lower interfacial layer LCb may include at least one of titanium (Ti), tantalum (Ta), tungsten (W), nickel (Ni), cobalt (Co), platinum (Pt), a nitride thereof, or a combination thereof. However, embodiments of the present disclosure are not limited thereto. Alternatively, the lower interfacial layer LCb may include, for example, a silicide obtained by reacting an element (e.g., silicon (Si)) included in the source/drain patterns 280a to 280f with a metal element. For example, the lower interfacial layer LCb may include a metal silicide such as nickel silicide, cobalt silicide, tungsten silicide, titanium silicide, niobium silicide, or tantalum silicide. However, embodiments of the present disclosure are not limited thereto.

The first semiconductor layer 282 may include a first oxide semiconductor material, and the second semiconductor layer 284 may include a second oxide semiconductor material. For example, the first oxide semiconductor material and the second oxide semiconductor material may be different from the material of the first active pattern AP1 and the second active pattern AP2. In some embodiments, the first semiconductor layer 282 and the second semiconductor layer 284 may include the same type of oxide semiconductor material. For example, each of the first oxide semiconductor material and the second oxide semiconductor material may be IGZO.

In some embodiments, the first oxide semiconductor material and the second oxide semiconductor material may have different characteristics. For example, the first oxide semiconductor material and the second oxide semiconductor material may have oxygen vacancies at different concentrations.

In some embodiments, the first semiconductor layer 282 and the second semiconductor layer 284 may be formed in different processes. For example, the first oxide semiconductor material may be formed in a physical vapor deposition (PVD) process, and the second oxide semiconductor material may be formed in an atomic layer deposition (ALD) process. In this case, a first oxygen vacancy concentration of the first oxide semiconductor material may be greater than a second oxygen vacancy concentration of the second oxide semiconductor material.

Accordingly, the first circuit element TR1 provided as the first transistor and the second circuit element TR2 provided as the second transistor may have different threshold voltages. For example, the first circuit element TR1 may have a first threshold voltage, and the second circuit element TR2 may have a second threshold voltage greater than the first threshold voltage.

In FIG. 3A, a thickness T11 of the first semiconductor layer 282 and a thickness T12 of the second semiconductor layer 284 are illustrated as being equal to each other, but this is only an example. In some embodiments, unlike what is shown, the thickness T11 of the first semiconductor layer 282 may be smaller or greater than the thickness T12 of the second semiconductor layer 284.

Each of the first gate dielectric pattern 290a, the second gate dielectric pattern 290b, and the third gate dielectric pattern 290c may include, for example, at least one of silicon oxide, silicon oxynitride, silicon nitride, and a high-k material having a dielectric constant greater than that of silicon oxide. However, embodiments of the present disclosure are not limited thereto.

In some embodiments, a thickness T21 of the first gate dielectric pattern 290a, a thickness T22 of the second gate dielectric pattern 290b, and a thickness T23 of the third gate dielectric pattern 290c may be equal to each other. In some embodiments, the first gate dielectric pattern 290a, the second gate dielectric pattern 290b, and the third gate dielectric pattern 290c may be formed at the same level. For example, the first gate dielectric pattern 290a, the second gate dielectric pattern 290b, and the third gate dielectric pattern 290c may include the same dielectric material (or the same material composition).

In some embodiments, the first gate pattern 292 may include a first lower conductive pattern 292a, a first interfacial layer 292b, and a first upper conductive pattern 292c, which are sequentially stacked on the first gate dielectric pattern 290a. In some embodiments, the second gate pattern 294 may include a second lower conductive pattern 294a, a second interfacial layer 294b, and a second upper conductive pattern 294c, which are sequentially stacked on the second gate dielectric pattern 290b. In some embodiments, the third gate pattern 296 may include a third interfacial layer 296b and a third upper conductive pattern 296c sequentially stacked on the third semiconductor layer 286.

The first lower conductive pattern 292a may fill at least a portion of the first trench 282t. The second lower conductive pattern 294a may fill at least a portion of the second trench 284t. Each of the first lower conductive pattern 292a and the second lower conductive pattern 294a may include a conductive material, for example, at least one of polysilicon, TiN, TiSiN, tungsten, tungsten silicide, and combinations thereof. However, embodiments of the present disclosure are not limited thereto. For example, each of the first lower conductive pattern 292a and the second lower conductive pattern 294a may include an amorphous polysilicon film.

The first interfacial layer 292b may be interposed between the first lower conductive pattern 292a and the first upper conductive pattern 292c. The second interfacial layer 294b may be interposed between the second lower conductive pattern 294a and the second upper conductive pattern 294c. Each of the first interfacial layer 292b and the second interfacial layer 294b may include, for example, a metal or a metal nitride for preventing or suppressing diffusion of a metal element included in the first upper conductive pattern 292a and/or the second upper conductive pattern 294c. For example, each of the first interfacial layer 292b and the second interfacial layer 294b may include at least one of titanium (Ti), tantalum (Ta), tungsten (W), nickel (Ni), cobalt (Co), platinum (Pt), a nitride thereof, or a combination thereof. However, embodiments of the present disclosure are not limited thereto. Alternatively, each of the first interfacial layer 292b and the second interfacial layer 294b may include, for example, silicide obtained by reacting elements (e.g., silicon (Si)) included in the first lower conductive pattern 292a and/or the second lower conductive pattern 294a with a metal element. For example, each of the first interfacial layer 292b and the second interfacial layer 294b may include a metal silicide such as nickel silicide, cobalt silicide, tungsten silicide, titanium silicide, niobium silicide, or tantalum silicide. However, embodiments of the present disclosure are not limited thereto.

The third interfacial layer 296b may be interposed between the third semiconductor layer 286 and the third upper conductive pattern 296c. The third interfacial layer 296b may include, for example, a metal or a metal nitride for preventing or suppressing diffusion of a metal element included in the first upper conductive pattern 292c and/or the second upper conductive pattern 294c. For example, each of the first interfacial layer 292b and the second interfacial layer 294b may include at least one of titanium (Ti), tantalum (Ta), tungsten (W), nickel (Ni), cobalt (Co), platinum (Pt), a nitride thereof, or a combination thereof. However, embodiments of the present disclosure are not limited thereto.

Each of the first upper conductive pattern 292c, the second upper conductive pattern 294c, and the third upper conductive pattern 296c may include a conductive material, for example, at least one of aluminum (Al), copper (Cu), tungsten (W), molybdenum (Mo), cobalt (Co), or an alloy thereof. However, embodiments of the present disclosure are not limited thereto.

Referring to FIG. 3B, in some embodiments, the first circuit element TR1 provided as a first transistor and the second circuit element TR2 provided as a second transistor may have different gate lengths.

For example, a first gate length L1 of the first gate pattern 292 may be smaller than a second gate length L2 of the second gate pattern 294. Accordingly, the first threshold voltage of the first circuit element TR1 may be lower than the second threshold voltage of the second circuit element TR2. The first gate length L1 may be defined as, for example, a length of a lower surface of the first gate pattern 292 in a horizontal direction in which the first source/drain area 282b and the second source/drain area 282c are arranged. The second gate length L2 may be defined as, for example, a length of the lower surface of the second gate pattern 294 in a horizontal direction in which the third source/drain area 284b and the fourth source/drain area 284c are arranged.

Referring to FIG. 3C, in some embodiments, the first support layer 270 may include a first recess 270r1 and a second recess 270r2.

The first recess 270r1 may be formed by recessing a portion of the upper surface of the first support layer 270 between the first source/drain pattern 280a and the second source/drain pattern 280b downwardly. The first semiconductor layer 282 may fill at least a portion of the first recess 270r1. For example, the first channel area 282a may conformally extend along a profile of a lower surface of the first recess 270r1.

The second recess 270r2 may be formed by recessing a portion of the upper surface of the first support layer 270 between the third source/drain pattern 280c and the fourth source/drain pattern 280d downwardly. The second semiconductor layer 284 may fill at least a portion of the second recess 270r2. For example, the second channel area 284a may conformally extend along a profile of a lower surface of the second recess 270r2.

Referring to FIG. 4A, in some embodiments, the third semiconductor layer 286 may include the first oxide semiconductor material.

For example, the first semiconductor layer 282 and the third semiconductor layer 286 may be formed at the same level. For example, both the first semiconductor layer 282 and the third semiconductor layer 286 may be formed in a PVD process. In some embodiments, a thickness T11 of the first semiconductor layer 282 and a thickness T13 of the third semiconductor layer 286 may be equal to each other.

Referring to FIG. 4B, in some embodiments, the third semiconductor layer 286 may include the second oxide semiconductor material.

For example, the second semiconductor layer 284 and the third semiconductor layer 286 may be formed at the same level as each other. For example, both the second semiconductor layer 284 and the third semiconductor layer 286 may be formed in an ALD process. In some embodiments, a thickness T12 of the second semiconductor layer 284 and a thickness T14 of the third semiconductor layer 286 may be equal to each other.

Referring to FIG. 4C, in some embodiments, the third semiconductor layer 286 may include a first sub-semiconductor layer 2861 and a second sub-semiconductor layer 2862 sequentially stacked on the upper surface of the first support layer 270.

Referring to FIG. 4D, in some embodiments, the third semiconductor layer 286 may include the second sub-semiconductor layer 2862 and the first sub-semiconductor layer 2861 sequentially stacked on the upper surface of the first support layer 270.

The first sub-semiconductor layer 2861 may include the first oxide semiconductor material. For example, the first semiconductor layer 282 and the first sub-semiconductor layer 2861 may be formed at the same level. For example, both the first semiconductor layer 282 and the first sub-semiconductor layer 2861 may be formed in a PVD process. In some embodiments, a thickness T11 of the first semiconductor layer 282 and a thickness T13 of the first sub-semiconductor layer 2861 may be equal to each other.

The second sub-semiconductor layer 2862 may include the second oxide semiconductor material. For example, the second semiconductor layer 284 and the second sub-semiconductor layer 2862 may be formed at the same level. For example, both the second semiconductor layer 284 and the second sub-semiconductor layer 2862 may be formed in an ALD process. In some embodiments, a thickness T12 of the second semiconductor layer 284 and a thickness T14 of the second sub-semiconductor layer 2862 may be equal to each other.

Referring to FIG. 4E, in some embodiments, the first support layer 270 may include a third recess 270r3.

The third recess 270r3 may be formed by recessing a portion of the upper surface of the first support layer 270 between the fifth source/drain pattern 280e and the sixth source/drain pattern 280f downwardly. The third semiconductor layer 286 may fill at least a portion of the third recess 270r3. For example, the third channel area 286a may conformally extend along a profile of a lower surface of the third recess 270r3.

The circuit elements TR1, TR2, and FC1 may provide an additional electronic circuit, such as a logic circuit (e.g., including a NAND, OR, XOR, NOT (an inverter), NAND, NOR, and/or an XNOR gate), a test circuit, and/or a trimming circuit, on the peripheral circuit structure PC. FIG. 5 illustrates an inverter as an electronic circuit provided by the circuit elements TR1, TR2, and FC1, but this is only an example. Those of ordinary skill in the art will understand that various other logic circuits, test circuits, and/or trimming circuits may be embodied as the circuit elements TR1, TR2, and FC1.

Referring to FIG. 5, in some embodiments, the circuit elements TR1, TR2, and FC1 may provide or act as an NFET (n-channel field-effect transistor) inverter circuit. For example, the circuit including the circuit elements TR1, TR2, and FC1 may not be used (inactive) in a normal operation state (which includes multiple operating modes) of the semiconductor memory device. For example, the circuit including the circuit elements TR1, TR2, and FC1 may be a logic circuit, a test circuit, and/or a trimming circuit. For example, the circuit including the circuit elements TR1, TR2, and FC1 may be used (or enabled or activated) only in an abnormal-operation state or programming mode), for example, to change the operation mode of the semiconductor memory device. For example, the circuit elements TR1, TR2, and FC1 may constitute a circuit configured to be programmed in a test and/or programming mode. In the test and/or programming mode, a programming signal (e.g., voltage and/or current) may be applied to a fuse or anti-fuse to set one or more non-volatile and/or irreversible states. After programming, upon power-up or release of reset, the stored states may be read and may be used during normal operation to select one of multiple operating modes of the semiconductor memory device. In some embodiments, the states may be latched into configuration registers at power-up or reset and may remain unchanged during normal operation.

For example, the first circuit element TR1 and the second circuit element TR2 may be electrically connected in series with each other and be electrically connected to and disposed between a first power node V_{SS} and a second power node V_{DD}. The first circuit element TR1 having a relatively low threshold voltage (the first threshold voltage) may be provided as a load NFET of the NFET inverter, and the second circuit element TR2 having a relatively high threshold voltage (the second threshold voltage) may be provided as a drive NFET of the NFET inverter.

For example, a source (e.g., the fourth source/drain pattern 280d) of the second circuit element TR2 may be electrically connected to the first power node V_{SS}, and a drain of the first circuit element TR1 may contact and be electrically connected to the second power node V_{DD}. An input signal Vᵢₙ of the NFET inverter may be input to a gate (e.g., the first gate pattern 292) of the first circuit element TR1 and a gate (e.g., the second gate pattern 294) of the second circuit element TR2. An output signal Vₒᵤₜ of the NFET inverter may be output from a node to which the source of the first circuit element TR1 and the drain of the second circuit element TR2 are electrically connected.

In some embodiments, the output signal Vₒᵤₜ of the NFET inverter may be electrically connected to the third circuit element FC1 provided as the fuse circuit element and/or the anti-fuse circuit element. For example, the fuse circuit element and/or the anti-fuse circuit element may be configured to be programmed (electrically connected or disconnected) to select a predetermined operating mode of the semiconductor memory device among a plurality of operating modes.

As the semiconductor memory device becomes more highly integrated, it is difficult to form an additional electronic circuit such as a logic circuit, a test circuit, and/or a trimming circuit on the core/peripheral area. In addition, as the aspect ratio of the capacitor on the cell area continuously increases, a process problem occurs due to a structural step difference between the cell area and the core/peripheral area.

The semiconductor memory device according to some embodiments may provide an additional electronic circuit on the peripheral circuit structure PC using the circuit elements TR1, TR2, and FC1. Specifically, as described above, each of the circuit elements TR1, TR2, and FC1 may be disposed at a level similar to that of the capacitor structure CAP to provide an additional electronic circuit such as a logic circuit, a test circuit, and/or a trimming circuit. In addition, the circuit elements TR1, TR2, and FC1 may eliminate or reduce the structural step difference between the first area CELL provided as the cell area and the second area C/P provided as the core/peripheral area. Accordingly, the semiconductor memory device with improved performance and integration may be provided.

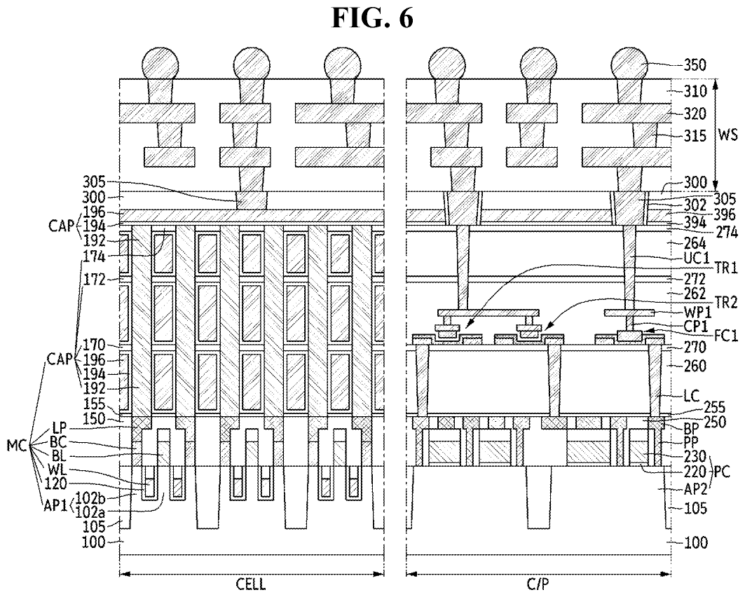

FIG. 6 is a cross-sectional view illustrating a semiconductor memory device according to some embodiments. For convenience of description, contents duplicate with those described above with reference to FIGS. 1 to 5 will be briefly described or the description thereof will be omitted.

Referring to FIG. 6, the semiconductor memory device according to some embodiments further includes an insulating capping film 394 and/or a conductive capping film 396.

The insulating capping film 394 may be deposited on the third support layer 274. The insulating capping film 394 may conformally extend along an upper surface of the third support layer 274. In some embodiments, the insulating capping film 394 may be disposed at the same level as that of the capacitor dielectric film 194 on an upper surface of the third support pattern 174. In some embodiments, the insulating capping film 394 may be formed at the same level as that of the capacitor dielectric film 194. For example, the capacitor dielectric film 194 and the insulating capping film 394 may include the same dielectric material (or the same material composition).

The conductive capping film 396 may be deposited on the insulating capping film 394. The conductive capping film 396 may conformally extend along an upper surface of the insulating capping film 394. In some embodiments, the conductive capping film 396 may be disposed on the same level as that of the upper electrode pattern 196 on an upper surface of the third support pattern 174. In some embodiments, the conductive capping film 396 may be formed at the same level as that of the upper electrode pattern 196. For example, the upper electrode pattern 196 and the conductive capping layer 396 may include the same conductive material (or the same material composition).

The insulating capping film 394 and/or the conductive capping film 396 may serve as a protective film for protecting the structures on the second area C/P. In some embodiments, one of the insulating capping film 394 and the conductive capping film 396 may be omitted.

In some embodiments, a via contact 305 may extend through the insulating capping film 394 and/or the conductive capping film 396 so as to contact and be electrically connected to the first upper contact UC1. For example, an insulating spacer 302 extending along a side surface of the via contact 305 may be formed. The via contact 305 may be electrically isolated from the conductive capping layer 396 via the insulating spacer 302.

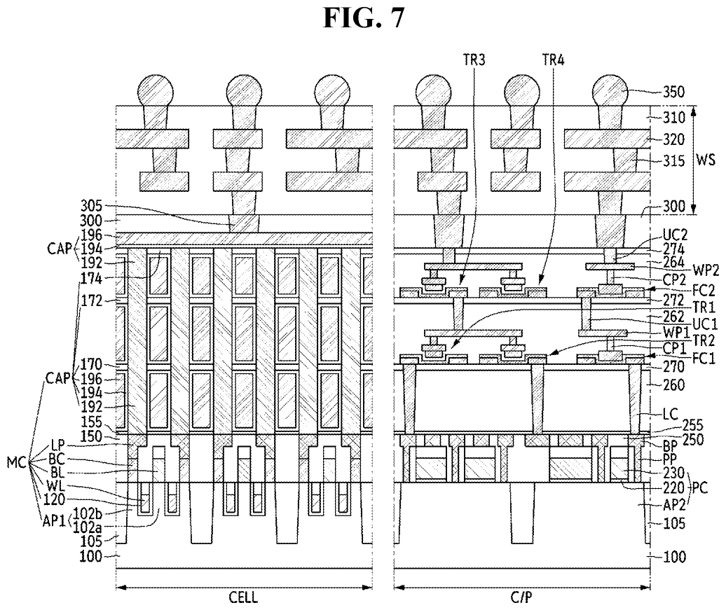

FIG. 7 is a cross-sectional view illustrating a semiconductor memory device according to some embodiments. For convenience of description, contents duplicate with those described above with reference to FIGS. 1 to 6 will be briefly described or the description thereof will be omitted.

Referring to FIG. 7, the semiconductor memory device according to some embodiments further includes fourth to sixth circuit elements TR3, TR4, and FC2.

The fourth to sixth circuit elements TR3, TR4, and FC2 may be formed on an upper surface of the second support layer 272. The third interlayer insulating film 264 may cover the fourth to sixth circuit elements TR3, TR4, and FC2. The fourth to sixth circuit elements TR3, TR4, and FC2 may be similar to the first to third circuit elements TR1, TR2, and FC1 described above with reference to FIGS. 1 to 5, respectively, and thus a detailed description thereof will be omitted below.

In some embodiments, at least some of the fourth to sixth circuit elements TR3, TR4, and FC2 may be electrically connected to the peripheral circuit structure PC, the first circuit element TR1, the second circuit element TR2, or the third circuit element FC1. For example, the first upper contact UC1 may electrically connect at least some of the first to third circuit elements TR1, TR2, and FC1 and at least some of the fourth to sixth circuit elements TR3, TR4, and FC2 to each other.

In some embodiments, at least some of the fourth to sixth circuit elements TR3, TR4, and FC2 may be electrically connected to each other. For example, a second contact pattern CP2 contacting and electrically connected to each of the fourth to sixth circuit elements TR3, TR4, and FC2 may be formed in the third interlayer insulating film 264. In addition, a second connection pattern WP2 contacting and electrically connected to the second contact pattern CP2 may be formed in the second interlayer insulating film 262. At least some of the fourth to sixth circuit elements TR3, TR4, and FC2 may be electrically connected to each other via the second contact pattern CP2 and/or the second connection pattern WP2.

In some embodiments, the wiring structure WS on the second area C/P may be electrically connected to the fourth to sixth circuit elements TR3, TR4, and FC3. For example, a second upper contact UC2 may be formed to extend through the third support layer 274 so as to contact and be electrically connected to the second connection pattern WP2. The wiring structure WS may be electrically connected to the fourth to sixth circuit elements TR3, TR4, and FC2 via the second upper contact UC2 and/or the via contact 305.

For example, the circuit elements TR1, TR2, FC2, TR3, TR4, and FC3 may collectively constitute a circuit described above with reference to FIG. 5 or a similar circuit, and thus a detailed description (including the operation) thereof is omitted.

Hereinafter, a method for manufacturing a semiconductor memory device according to some embodiments will be described with reference to FIGS. 1 to 30.

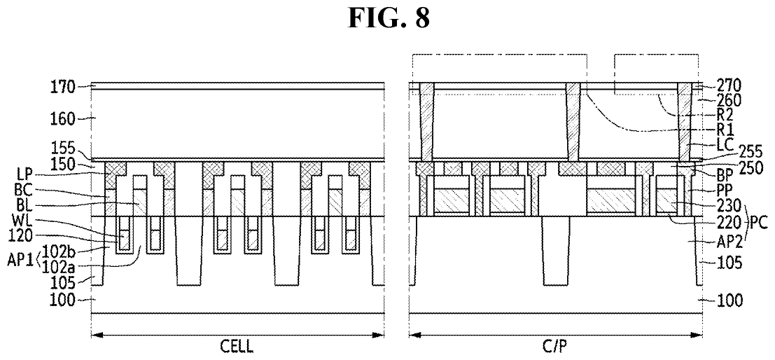

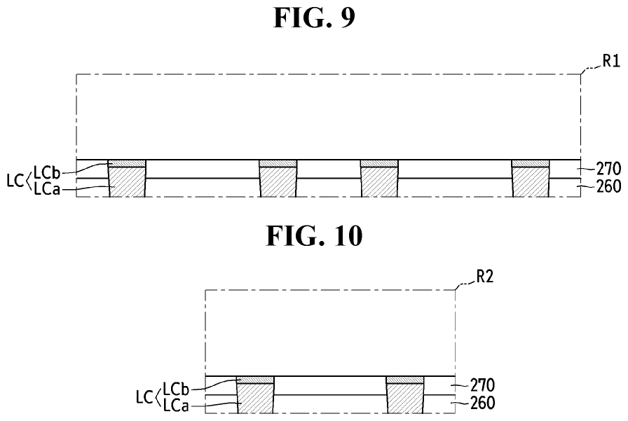

FIGS. 8 to 30 are diagrams for illustrating intermediate structures corresponding to intermediate steps of a method for manufacturing a semiconductor memory device according to some embodiments. For convenience of description, contents duplicate with those described above with reference to FIGS. 1 to 7 will be briefly described or the description thereof will be omitted. For reference, FIG. 9 is an enlarged view for illustrating an area R1 of FIG. 8, and FIG. 10 is an enlarged view for illustrating an area R2 of FIG. 8.

Referring to FIGS. 8 to 10, the element isolation pattern 105, the first active pattern AP1, the first gate dielectric film 120, the word line WL, the bit line BL, the first lower interlayer insulating film 150, the contact structure BC and LP, and the first etch stop film 155 may be formed on the first area CELL of the substrate 100. In addition, the peripheral circuit structure PC, the second lower interlayer insulating film 250, the plug pattern PP, the peripheral circuit wiring BP, and the second etch stop film 255 may be formed on the second area C/P of the substrate 100.

Subsequently, a first sacrificial film 160 and the first support pattern 170 may be sequentially formed on the first etch stop film 155, and the first interlayer insulating film 260 and the first support layer 270 may be sequentially formed on the second etch stop film 255. The first sacrificial film 160 and the first interlayer insulating film 260 may be formed at the same level. The first support pattern 170 and the first support layer 270 may be formed at the same level.

Subsequently, the lower contact LC extending through the second etch stop film 255, the first interlayer insulating film 260, and the first support layer 270 may be formed on the second area C/P.

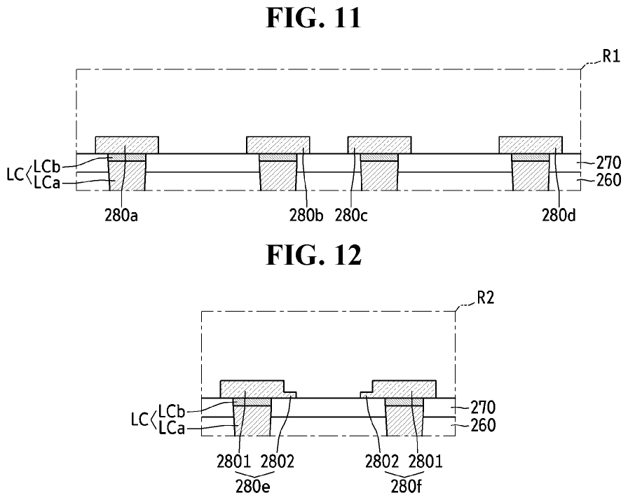

Referring to FIGS. 11 and 12, the source/drain patterns 280a to 280f may be formed on the first support layer 270.

At least some of the source/drain patterns 280a to 280f may contact and be electrically connected to the lower contact LC. Each of the source/drain patterns 280a to 280f may include, but is not limited to, an amorphous polysilicon film.

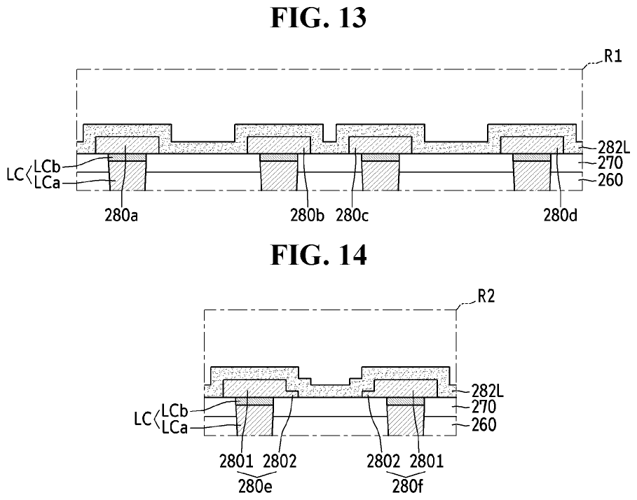

Referring to FIGS. 13 and 14, a first oxide semiconductor layer 282L is formed on the first support layer 270 and the source/drain patterns 280a to 280f.

The first oxide semiconductor layer 282L may conformally extend along the first support layer 270 and the source/drain patterns 280a to 280f. The first oxide semiconductor layer 282L may include the first oxide semiconductor material. For example, the first oxide semiconductor layer 282L may include IGZO formed in a PVD process.

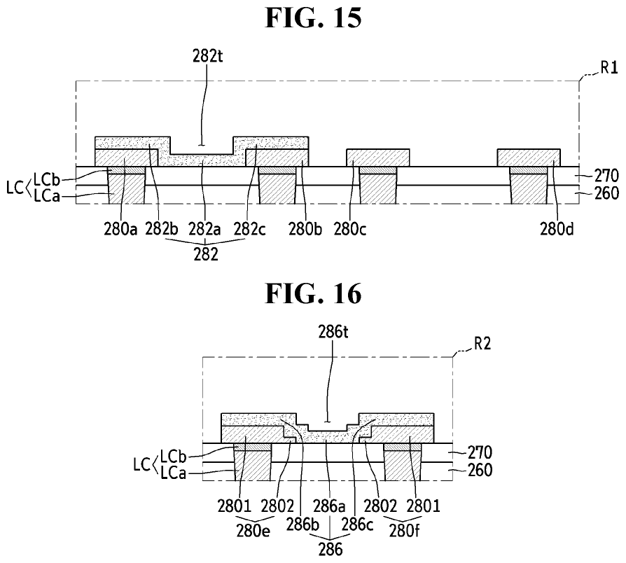

Referring to FIGS. 15 and 16, the first semiconductor layer 282 and the third semiconductor layer 286 are formed.

For example, a patterning process may be performed on the first oxide semiconductor layer 282L of FIGS. 13 and 14. As the patterning process is performed, a first semiconductor layer 282 connecting the first source/drain pattern 280a and the second source/drain pattern 280b to each other may be formed. In addition, as the patterning process is performed, the third semiconductor layer 286 connecting the fifth source/drain pattern 280e and the sixth source/drain pattern 280f to each other may be formed.

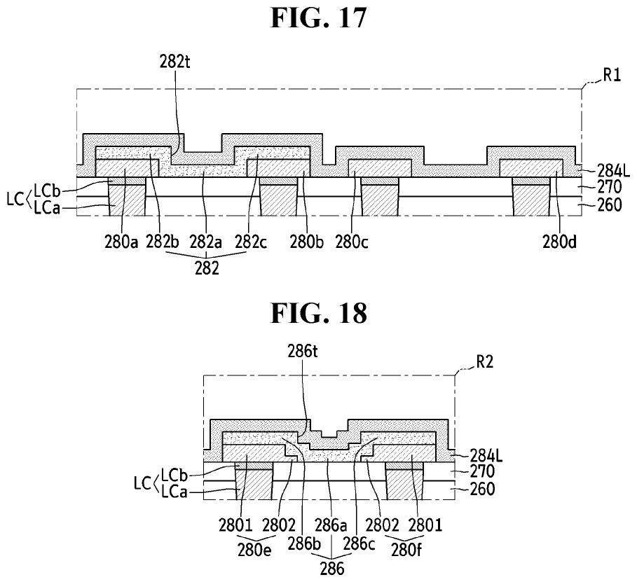

Referring to FIGS. 17 and 18, a second oxide semiconductor layer 284L is formed on the first support layer 270, the first semiconductor layer 282, the third source/drain pattern 280c, the fourth source/drain pattern 280d, and the third semiconductor layer 286.

The second oxide semiconductor layer 284L may conformally extend along the first support layer 270, the first semiconductor layer 282, the third source/drain pattern 280c, the fourth source/drain pattern 280d, and the third semiconductor layer 286. The second oxide semiconductor layer 284L may include the second oxide semiconductor material. For example, the second oxide semiconductor layer 284L may include IGZO formed in an ALD process.

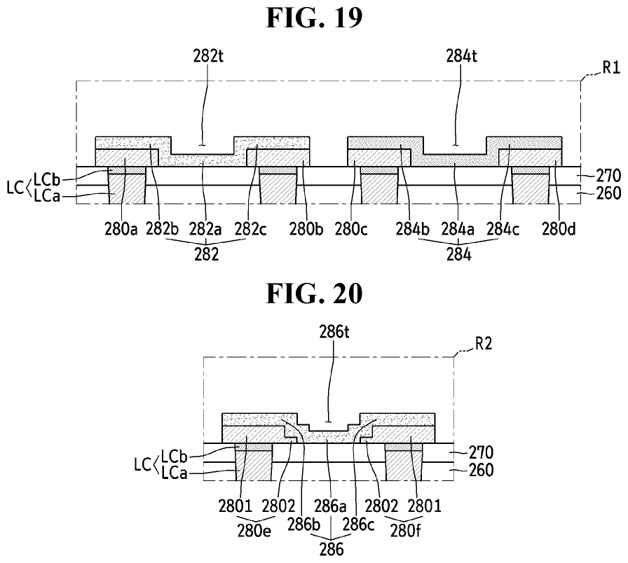

Referring to FIGS. 19 and 20, the second semiconductor layer 284 is formed.

For example, a patterning process may be performed on the second oxide semiconductor layer 284L of FIGS. 17 and 18. As the patterning process is performed, the second semiconductor layer 284 connecting the third source/drain pattern 280c and the fourth source/drain pattern 280d to each other may be formed.

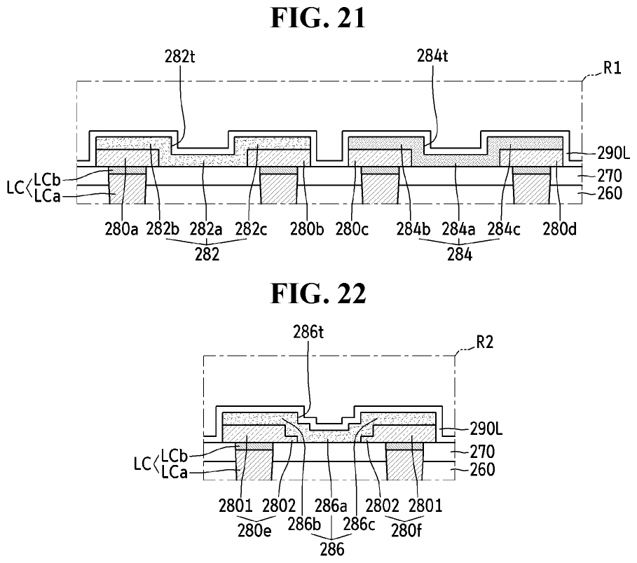

Referring to FIGS. 21 and 22, a third gate dielectric film 290L is formed on the first support layer 270, the first semiconductor layer 282, the second semiconductor layer 284, and the third semiconductor layer 286.

The third gate dielectric film 290L may conformally extend along the first support layer 270, the first semiconductor layer 282, the second semiconductor layer 284, and the third semiconductor layer 286. The third gate dielectric film 290L may include, for example, at least one of silicon oxide, silicon oxynitride, silicon nitride, and a high dielectric constant (high-k) material having a dielectric constant greater than that of silicon oxide. However, embodiments of the present disclosure are not limited thereto.

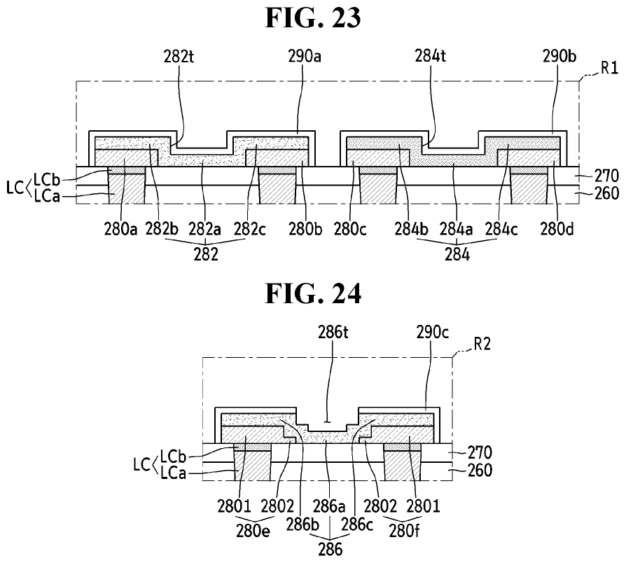

Referring to FIGS. 23 and 24, the first gate dielectric pattern 290a, the second gate dielectric pattern 290b, and the third gate dielectric pattern 290c are formed.

For example, a patterning process may be performed on the third gate dielectric film 290L of FIGS. 21 and 22. As the patterning process is performed, the first gate dielectric pattern 290a covering an upper surface of the first semiconductor layer 282 may be formed. In addition, as the patterning process is performed, the second gate dielectric pattern 290b covering an upper surface of the second semiconductor layer 284 may be formed. In addition, as the patterning process is performed, the third gate dielectric pattern 290c may be formed to cover a portion of an upper surface of the third semiconductor layer 286. For example, the third gate dielectric pattern 290c may not cover at least a portion of the third channel area 286a of the third semiconductor layer 286 so as to be exposed.

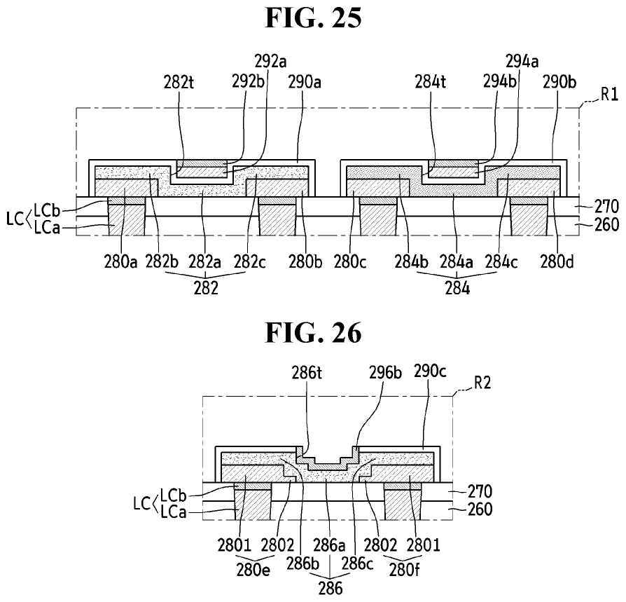

Referring to FIGS. 25 and 26, the first lower conductive pattern 292a, the first interfacial layer 292b, the second lower conductive pattern 294a, the second interfacial layer 294b, and the third interfacial layer 296b are formed.

The first lower conductive pattern 292a may fill at least a portion of the first trench 282t. The first interfacial layer 292b may extend along an upper surface of the first lower conductive pattern 292a. The second lower conductive pattern 294a may fill at least a portion of the second trench 284t. The second interfacial layer 294b may be formed to extend along an upper surface of the second lower conductive pattern 294a. The third interfacial layer 296b may conformally extend along the profile of the third trench 286t.

In some embodiments, the first lower conductive pattern 292a and the second lower conductive pattern 294a may be formed at the same level. In some embodiments, the first interfacial layer 292b, the second interfacial layer 294b, and the third interfacial layer 296b may be formed at the same level.

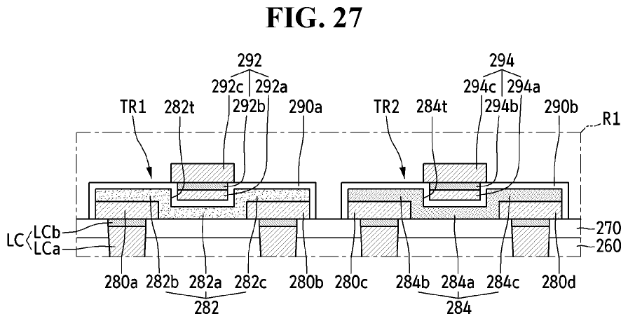

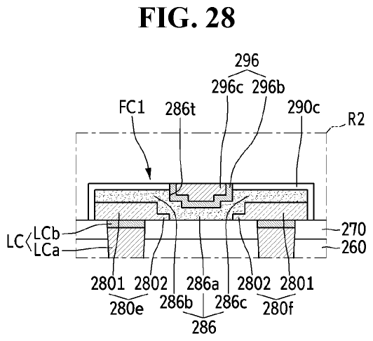

Referring to FIGS. 27 and 28, the first upper conductive pattern 292c, the second upper conductive pattern 294c, and the third upper conductive pattern 296c may be formed.

The first upper conductive pattern 292c may contact and be electrically connected to an upper surface of the first interfacial layer 292b. Accordingly, the first circuit element TR1 including the first semiconductor layer 282 and the first gate pattern 292 may be formed. The second upper conductive pattern 294c may contact and be electrically connected to an upper surface of the second interfacial layer 294b. Accordingly, the second circuit element TR2 including the second semiconductor layer 284 and the second gate pattern 294 may be formed. The third upper conductive pattern 296c may contact and be electrically connected to an upper surface of the third interfacial layer 296b. The third upper conductive pattern 296c may fill at least a portion of the third trench 286t. Accordingly, the third circuit element FC1 including the third semiconductor layer 286 and the third gate pattern 296 may be formed.

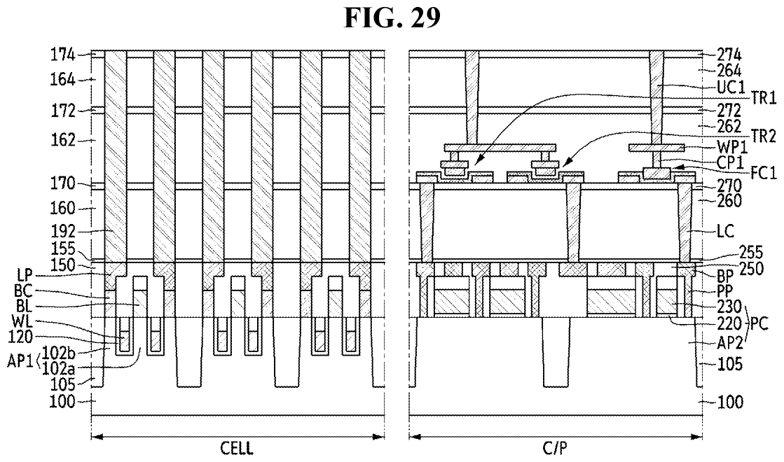

Referring to FIG. 29, a second sacrificial film 162, the second support pattern 172, a third sacrificial film 164, and the third support pattern 174 may be sequentially formed on the first support pattern 170. In addition, the second interlayer insulating film 262, the second support layer 272, the third interlayer insulating film 264, and the third support layer 274 are sequentially formed on the circuit elements TR1, TR2, and FC1.

The second sacrificial film 162 and the second interlayer insulating film 262 may be formed at the same level. The second support pattern 172 and the second support layer 272 may be formed at the same level. The third sacrificial film 164 and the third interlayer insulating film 264 may be formed at the same level. The third support pattern 174 and the third support layer 274 may be formed at the same level.

Subsequently, the lower electrode pattern 192 contacting and electrically connected to the contact structure BC and LP is formed. For example, the lower electrode pattern 192 may extend through the first etch stop film 155, the first sacrificial film 160, the first support pattern 170, the second sacrificial film 162, the second support pattern 172, the third sacrificial film 164, and the third support pattern 174 so as to contact and be electrically connected to the upper surface of the contact structure BC and LP.

In addition, the first contact pattern CP1 contacting and electrically connected to each of the circuit elements TR1, TR2, and FC1 may be formed in the second interlayer insulating film 262. In addition, the first connection pattern WP1 contacting and electrically connected to the first contact pattern CP1 may be formed in the second interlayer insulating film 262.

Subsequently, the first upper contact UC1 contacting and electrically connected to the first connection pattern WP1 may be formed. For example, the first upper contact UC1 may extend through the second support layer 272, the third interlayer insulating film 264, and the third support layer 274 so as to contact and be electrically connected to the first connection pattern WP1.

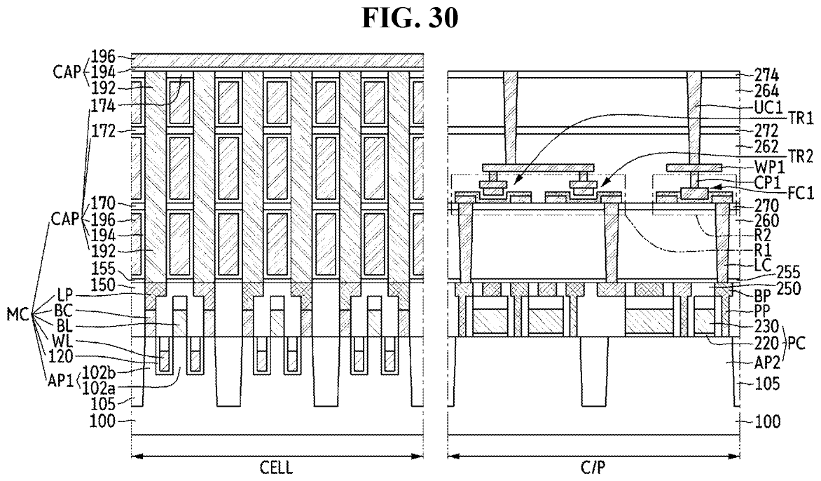

Referring to FIG. 30, the capacitor structure CAP is formed.

For example, the first sacrificial film 160, the second sacrificial film 162, and the third sacrificial film 164 may be selectively removed. Subsequently, the capacitor dielectric film 194 and the upper electrode pattern 196 may be formed on an area from which the first sacrificial film 160, the second sacrificial film 162, and the third sacrificial film 164 have been removed. As a result, the memory cell structure MC including the first active pattern AP1, the first gate dielectric film 120, the word line WL, the bit line BL, the contact structure BC and LP, and the capacitor structure CAP may be formed.

Next, referring to FIG. 2, the upper interlayer insulating film 300, the via contact 305, the wiring structure WS, and the contact terminal 350 are formed. In this way, the semiconductor memory device as described above using FIGS. 1 to 5 may be manufactured.

According to embodiments of the present disclosure, the test/programing circuit described with reference to FIG. 5 may be positioned apart from the information-storage cells (e.g., the memory cell structure MC on the first area CELL) and from other internal circuits (e.g., the peripheral circuit structure PC formed on the second area C/P). In addition, the test/programing circuit may be connected to the input and output terminals (e.g., contact terminal 350) and to an external circuit through a conductive path (e.g., a part of the wiring structure WS) of reduced or minimized length. If this arrangement is not applied, the test/programing circuit is typically part of the other internal circuits. However, an arrangement in which the test/programing circuit is included separately from the peripheral circuit structure PC may facilitate programming from the external circuit by reducing adverse effects (such as voltage drop, series impedance, signal delay, and noise coupling), which may otherwise occur when high voltage and high current are applied during programming. The short connection path to the terminals, together with the physical separation from the cells and other circuits, may help to mitigate electrical stress and suppress undesirable effects such as dielectric stress and electromigration. As a result, the quality of the test/program operation may be improved, and memory cells MC and sensitive circuitry formed on the second area C/P may be better protected

Although embodiments of the present disclosure have been described above with reference to the accompanying drawings, the present invention is not limited to these embodiments and may be implemented in various different forms. Those of ordinary skill in the technical field to which the present disclosure belongs will be able to appreciate that the present invention may be implemented in other specific forms. Therefore, it should be understood that embodiments as described above are not restrictive but illustrative in all respects.

What is claimed is:

1. A semiconductor memory device comprising:
a substrate including a first area and a second area;
a unit cell including:
a first active pattern disposed on the first area,
a bit line electrically connected to a first portion of the first active pattern;
a contact electrode electrically connected to a second portion of the first active pattern,
a word line intersecting the first active pattern between the first portion and the second portion, and
a capacitor electrically connected to an upper surface of the contact electrode;
a peripheral circuit layer including a second active pattern disposed on the second area, and a gate electrode intersecting the second active pattern; and
a first individual device disposed on an upper surface of the peripheral circuit layer, the first individual device being disposed at a vertical level between a lower surface of the capacitor and an upper surface of the capacitor,
wherein the first individual device includes a first semiconductor layer including a first oxide semiconductor material, and a first gate pattern intersecting the first semiconductor layer in a plan view.

2. The semiconductor memory device of claim 1, further comprising a first support layer, the first individual device being disposed on an upper surface of the first support layer,
wherein the capacitor includes:
a lower electrode pattern electrically connected to the upper surface of the contact electrode,
a first support pattern disposed on a side surface of the lower electrode pattern, and
a capacitor dielectric film and an upper electrode pattern sequentially stacked on the lower electrode pattern and the first support pattern, and
wherein the first support pattern and the first support layer are disposed at the same vertical level.

3. The semiconductor memory device of claim 2, further comprising a second support layer spaced apart from the upper surface of the first support layer in a vertical direction,
wherein the capacitor further includes a second support pattern disposed on the side surface of the lower electrode pattern and spaced apart from an upper surface of the first support pattern, and
wherein the second support pattern and the second support layer are disposed at the same vertical level.

4. The semiconductor memory device of claim 3, further comprising a second individual device disposed on an upper surface of the second support layer,
wherein the second individual device includes a second semiconductor layer including a second oxide semiconductor material, and a second gate pattern intersecting the second semiconductor layer.

5. The semiconductor memory device of claim 1, further comprising a lower contact extending in a direction intersecting an upper surface of the substrate and electrically connecting the peripheral circuit layer and the first individual device.

6. The semiconductor memory device of claim 1, further comprising a plurality of wiring patterns disposed on the upper surface of the capacitor and an upper surface of the first individual device, the plurality of wiring patterns formed of a multi-layers.

7. The semiconductor memory device of claim 6, further comprising an upper contact extending in a direction intersecting an upper surface of the substrate and electrically connecting the first individual device and the plurality of wiring patterns.

8. The semiconductor memory device of claim 1, wherein the first individual device further includes a gate dielectric pattern interposed between the first semiconductor layer and the first gate pattern.

9. The semiconductor memory device of claim 1, wherein the first gate pattern is in contact with the first semiconductor layer.

10. The semiconductor memory device of claim 1, wherein the first semiconductor layer includes a channel area disposed on a lower surface of the first gate pattern, a first source/drain area and a second source/drain area
wherein the first source/drain area and the second source/drain area are connected to opposing ends of the channel area, respectively, and
wherein the first individual device further includes a first source/drain pattern electrically connected to a lower surface of the first source/drain area, and a second source/drain pattern electrically connected to a lower surface of the second source/drain area.

11. The semiconductor memory device of claim 10, wherein an upper surface of the first semiconductor layer has a recess between the first source/drain pattern and the second source/drain pattern, and
wherein the first gate pattern at least partially fills the recess.

12. A semiconductor memory device comprising:
a substrate including a first area and a second area;
a first active pattern disposed on the first area;
a bit line electrically connected to a first portion of the first active pattern;
a capacitor including:
a lower electrode pattern electrically connected to a second portion of the first active pattern,
a support pattern disposed on a side surface of the lower electrode pattern, and
a capacitor dielectric film and an upper electrode pattern sequentially stacked on the lower electrode pattern and the support pattern;
a word line intersecting the first active pattern between the first portion and the second portion;
a peripheral circuit layer including a second active pattern disposed on the second area, and a gate electrode intersecting the second active pattern;
a support layer disposed on an upper surface of the peripheral circuit layer, the support pattern and the support layer being disposed at the same vertical level;
a first transistor disposed on an upper surface of the support layer; and
a second transistor disposed on the upper surface of the support layer,
wherein the first transistor includes:
a first semiconductor layer including a first oxide semiconductor material, and
a first gate pattern intersecting the first semiconductor layer, and
wherein the second transistor includes:
a second semiconductor layer including a second oxide semiconductor material, and a second gate pattern intersecting the second semiconductor layer,
wherein the first transistor has a first threshold voltage, and
wherein the second transistor has a second threshold voltage greater than the first threshold voltage.

13. The semiconductor memory device of claim 12, wherein a first oxygen vacancy concentration of the first oxide semiconductor material is greater than a second oxygen vacancy concentration of the second oxide semiconductor material.

14. The semiconductor memory device of claim 12, wherein the first semiconductor layer includes a channel area disposed on a lower surface of the first gate pattern, a first source/drain area and a second source/drain area
wherein the first source/drain area and the second source/drain area are connected to opposing ends of the channel area, respectively, and
wherein the first transistor further includes a first source/drain pattern electrically connected to a lower surface of the first source/drain area, and a second source/drain pattern electrically connected to a lower surface of the second source/drain area.

15. The semiconductor memory device of claim 12, wherein a first gate length of the first transistor is smaller than a second gate length of the second transistor.

16. The semiconductor memory device of claim 12, wherein each of the first oxide semiconductor material and the second oxide semiconductor material includes IGZO.

17. A semiconductor memory device comprising:
a substrate including a first area and a second area;
a first active pattern disposed on the first area;
a bit line electrically connected to a first portion of the first active pattern;
a capacitor including:
a lower electrode pattern electrically connected to a second portion of the first active pattern;
a support pattern disposed on a side surface of the lower electrode pattern; and
a capacitor dielectric film and an upper electrode pattern sequentially stacked on the lower electrode pattern and the support pattern;
a word line intersecting the first active pattern between the first portion and the second portion;
a peripheral circuit layer including a second active pattern disposed on the second area, and a gate electrode intersecting the second active pattern;
a support layer disposed on an upper surface of the peripheral circuit layer, the support layer and the support pattern being disposed at the same vertical level; and
a first individual device disposed on an upper surface of the support layer, the first individual device including a first semiconductor layer including an oxide semiconductor material, and an electrode pattern in contact with the first semiconductor layer.

18. The semiconductor memory device of claim 17, wherein the first semiconductor layer includes:
a first sub-semiconductor layer disposed on the upper surface of the support layer and including a first oxide semiconductor material; and
a second sub-semiconductor layer disposed on an upper surface of the first sub-semiconductor layer and including a second oxide semiconductor material.

19. The semiconductor memory device of claim 18, wherein a first oxygen vacancy concentration of the first oxide semiconductor material and a second oxygen vacancy concentration of the second oxide semiconductor material are different from each other.

20. The semiconductor memory device of claim 18, further comprising:
a second individual device disposed on the upper surface of the support layer, the second individual device including:
a second semiconductor layer including the first oxide semiconductor material,
a first gate pattern intersecting the second semiconductor layer, and
a first gate dielectric pattern interposed between the second semiconductor layer and the first gate pattern; and
a third individual device disposed on the upper surface of the support layer, the third individual device including:
a third semiconductor layer including the second oxide semiconductor material,
a second gate pattern intersecting the third semiconductor layer, and
a second gate dielectric pattern interposed between the third semiconductor layer and the second gate pattern.
